(19) United States
(12) Patent Application Publication
(10) Pub. No.: US 2023/0327424 A1
(43) Pub. Date: Oct. 12, 2023

(54) DIRECT CURRENT DISTRIBUTION SYSTEM, CONTROL APPARATUS, ANOMALY DETECTION METHOD AND PROGRAM

(71) Applicant: NIPPON TELEGRAPH AND TELEPHONE CORPORATION, Tokyo (JP)

(72) Inventors: Naoki HANAOKA, Tokyo (JP); Hidetoshi TAKADA, Tokyo (JP); Toshimitsu TANAKA, Tokyo (JP); Naomichi NAKAMURA, Tokyo (JP)

(21) Appl. No.: 18/042,486

(22) PCT Filed: Aug. 26, 2020
(86) PCT No.: PCT/JP2020/032212

§ 371 Date: Feb. 22, 2023

(51) Int. Cl. H02H 3/16; H02J 1/00; G01R 31/52

(52) U.S. Cl. CPC H02H 3/16; H02J 13/00; G01R 31/52; H02J 1/00

(57) ABSTRACT

A DC power distribution system for performing DC power distribution from a power distribution side base to one or more power reception side bases via a power distribution network includes measuring instruments provided at the power distribution side base and at the one or more power reception side bases, and a control device, in which the control device includes an operation unit that acquires a voltage value and a current value measured by the measuring instrument and calculates an output side power sum that is a sum of power output from the power distribution side base, a power reception side power sum that is a sum of power input to the one or more power reception side bases, and a loss sum between the power distribution side base and the one or more power reception side bases, and a control unit that detects an abnormality in the distribution network by comparing the output side power sum with a total sum of the power reception side power sum and the loss sum.

### TECHNICAL FIELD

The present invention relates to a technique for detecting an accident such as a ground fault or a short circuit that occurs in a power distribution system.

### BACKGROUND ART

In a power distribution system, it is necessary to take measures such as stopping power distribution from a power supply device in a case where an accident such as a ground fault or a short circuit is detected.

As an example of a device for detecting an accident such as a ground fault or a short circuit, a distance relay (for example, a mho relay described in NPL 1) is used at a transmission end of an AC substation or the like. The distance relay operates when a function of a ratio of voltage to current becomes a predetermined value or less with voltage and current as input amounts. This ratio is referred to as impedance viewed by the relay.

In communication buildings, data centers, or the like, high-voltage DC power distribution systems are introduced to reduce power loss of entire systems and achieve energy saving. In the high-voltage DC power distribution system, power distribution is performed by a high voltage such as 380 V.

### CITATION LIST

### Non Patent Literature

[NPL 1] Term description (22nd Theme: Mho relay), Journal of the institute of Electrical Engineers of Japan B (Journal of Electricity and Energy) Vol. 132 (2012) No. 8, https://www.jstage.jst.go.jp/article/ieejpes/132/8/132_NL8_6/_pdf

### SUMMARY OF INVENTION

### Technical Problem

Since the direct current used in the high-voltage DC power distribution system has no reactance, a distance relay such as a mho relay described in NPL 1 cannot be used. In addition, there is no distance relay for high-voltage DC power distribution such as 380 V on the market.

The present invention has been made in view of the above points, and an object of the present invention is to provide a technique capable of detecting an abnormality generated in a DC power distribution system.

### Solution to Problem

According to the disclosed technique, there is provided a DC power distribution system for performing DC power distribution from a power distribution side base to one or more power reception side bases via a power distribution network, the system including
measuring instruments provided at the power distribution side base and at the one or more power reception side bases, and
a control device, in which
the control device includes
an operation unit that acquires a voltage value and a current value measured by the measuring instrument and calculates an output side power sum that is a sum of power output from the power distribution side base, a power reception side power sum that is a sum of power input to the one or more power reception side bases, and a loss sum between the power distribution side base and the one or more power reception side bases, and
a control unit that detects an abnormality in the distribution network by comparing the output side power sum with a total sum of the power reception side power sum and the loss sum.

### Advantageous Effects of Invention

According to the disclosed technology, it is possible to detect an abnormality that has occurred in a DC power distribution system.

### BRIEF DESCRIPTION OF DRAWINGS

FIG. 1 is a diagram illustrating a configuration example of a system.

FIG. 2 is a diagram illustrating a connection example.

FIG. 3 is a diagram illustrating a configuration example of a control device 100.

FIG. 4 is a diagram illustrating a configuration example of a control device 200.

FIG. 5 is a diagram illustrating a configuration example of a learning device 300.

FIG. 6 is a diagram illustrating a hardware configuration example of a device.

FIG. 7 is a diagram illustrating a flowchart illustrating a processing procedure.

FIG. 8 is a diagram illustrating an example of a topology.

FIG. 9 is a diagram illustrating an example of the topology.

### DESCRIPTION OF EMBODIMENTS

Hereinafter, an embodiment of the present invention (the present embodiment) will be described with reference to the drawings. The embodiment to be described below is merely an example, and embodiments to which the present invention is applied are not limited to the following embodiment.

A DC power distribution system according to the embodiment is assumed to be a high-voltage DC distribution system that distributes power with a high-voltage DC such as 380 V. Here, distribution at a high voltage is an example. Further, the present invention is applicable not only to the high voltage DC distribution system but also to a DC distribution system in general.

### (System Configuration Example)

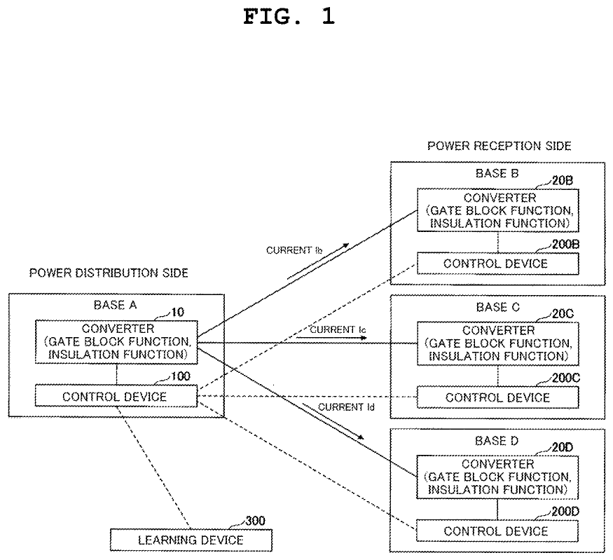

FIG. 1 illustrates a configuration example of a DC power distribution system in the present embodiment. The power distribution system in the present embodiment is a system for distributing power from a base A to a plurality of bases by direct current. In the example illustrated in FIG. 1, there are three bases, base B, base C, and base D, as bases on a power reception side. Each of the bases A to D is a building such as a communication building, but they are not limited to buildings.

As illustrated in FIG. 1, a converter 10 is provided at the base A on the power distribution side. More specifically, for example, a rectifying device for converting commercial power (AC) into DC is provided in front of the converter 10. A converter 20B, a converter 20C, and a converter 20D are provided at the base B, the base C, and the base D on the power reception side. Each converter is a DC-DC converter, which is a device that converts the magnitude of a DC voltage. A load such as a server is connected under the converter at the base on the power reception side.

The base on the power reception side may be provided with an inverter (DC/AC) instead of the converter. In the present embodiment, it is assumed that the base on the power reception side is provided with a converter. As illustrated in the figure, each converter (or inverter) has an insulating function and a gate block function.

In a case where the bases are not distinguished, the converter on the power reception side is described as “converter 20”.

The converter 10 of the base A and the converter 20 of each base are connected by a distribution line, and a DC current is distributed from the converter 10 of the base A to the converter 20 of each base. A distribution line in a DC power distribution system may be referred to as a “distribution network”.

The base A is provided with a control device 100, and the bases B to D are provided with a control device 200B, a control device 200C, and a control device 200D. In a case where the bases are not distinguished, the control device on the power reception side is described as “control device 200”. The control device 100 and each control device 200 are connected by a communication network.

The control device 100 may be a device inside the converter 10 or a device outside the converter 10. In addition, the control device 100 may be provided outside the base A. The control device 200 at each base on the power reception side may be a device inside the converter 20 or a device outside the converter 20. The control device 200 may be provided outside the base. In addition, one control device may be provided for a plurality of bases instead of the control device being provided for each base.

As illustrated in FIG. 1, a learning device 300 is provided. The learning device 300 may be installed anywhere, for example, a virtual machine on a cloud may be used as the learning device 300. The learning device 300 is connected to the control device 100 via a communication network. The learning device 300 may be further connected to the control device 200 at each base on the power reception side via a communication network. The control device 100 or the control device 200 may function as the learning device 300.

The converter 10 on the power distribution side and the converter 20 on the power reception side are provided with a current meter and a voltmeter (collectively referred to as measuring instruments). The measuring instruments may be provided inside the converters 10 and 20 or outside the converters 10 and 20.

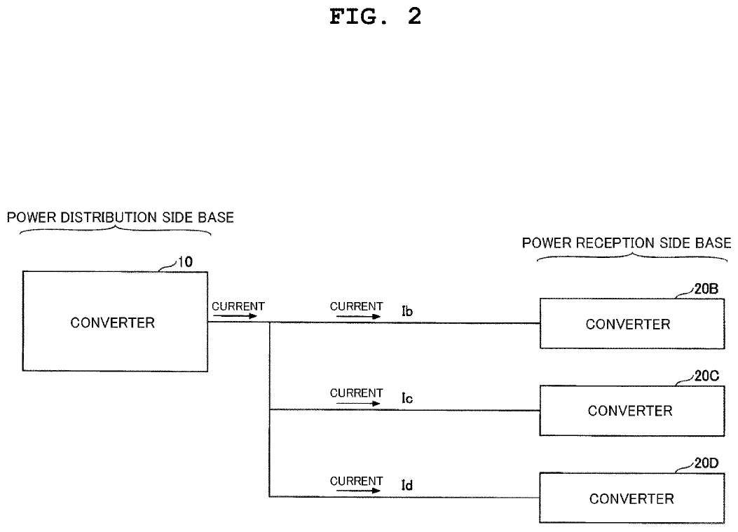

FIG. 2 is a diagram illustrating the connection of distribution lines. As illustrated in FIG. 2, at the base A on the power distribution side (converter 10), the distribution line from the output side of the converter 10 is branched and extends to three bases on the power reception side. Since the three power reception side bases are connected in parallel to the power distribution line on the output side, the voltage on the output side of the converter 10 is equally applied to the three branched distribution lines. A current I output from the output side of the converter 10 is branched into currents Ib, Ic, and Id. If the distribution network is normal, there is the relationship I=Ib+Ic+Id.

### (Operation Overview)

As illustrated in FIG. 1, in the present embodiment, the control device 100 is provided at the base A on the power distribution side, and the control devices 200B to 200D are provided at the base A on the power reception side. According to the technology of the present invention, although the main body for detecting an abnormality such as an accident may be a power distribution side control device 100 or a power reception side control device 200, the following description is made on the assumption that the control device 100 on the power distribution side performs a process for detecting an abnormality such as an accident.

The control device 100 at the base A on the distribution side acquires the voltage value and the current value on the secondary side (output side) of the converter 10 by acquiring the value of the measuring instrument.

The control device 200 at each base on the power reception side acquires the voltage value and the current value on the primary side (input side) of the converter 20 by acquiring the value of the measuring instrument. The control device 200 of each base on the power reception side transmits the acquired voltage value and current value of the primary side (input side) of the converter 20 to the control device 200 of the base A via the communication network.

The control device 200 performs abnormality detection (for example, short circuit detection, ground fault detection) in the distribution network based on the voltage value and the current value on the power distribution side and the voltage value and the current value of each base on the power reception side. The method of detecting an abnormality will be described later. In a case where the control device 200 detects an abnormality in the distribution network, for example, the control device executes processing such as displaying an alarm at the bases A to D, operating the gate block function of the converter 10, and stopping the distribution of power to the bases B to D.

### (Configuration Example of Control Device 100)

Configuration examples of the control device 100, the control device 200, and the learning device 300 in the DC power distribution system illustrated in FIG. 1 will be described. As described above, the configuration will be described by taking as an example the case where the control device 100 performs the abnormality detection process and the control device 200 performs monitoring, display, and the like.

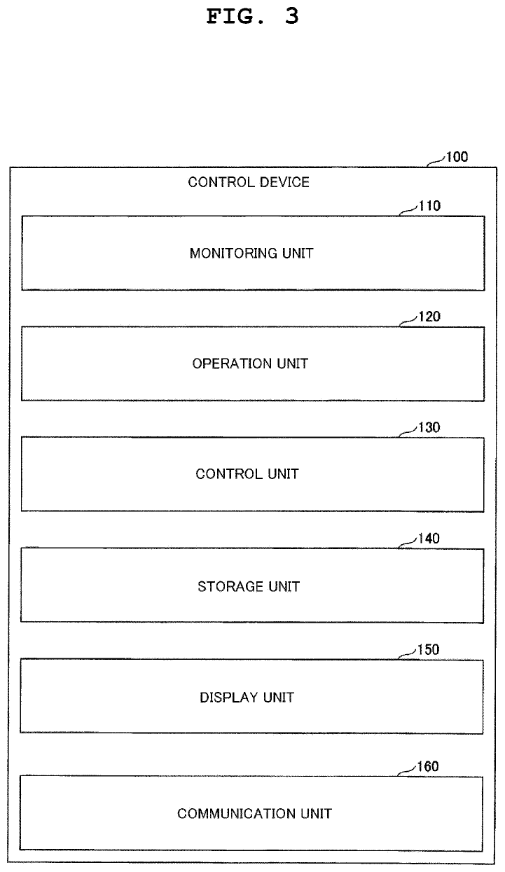

FIG. 3 illustrates a configuration example of the control device 100. As illustrated in FIG. 3, the control device 100 includes a monitoring unit 110, an operation unit 120, a control unit 130, a storage unit 140, a display unit 150, and a communication unit 160. The outline of the functions of each unit is as follows.

The monitoring unit 110 reads the values of a current meter and a voltmeter built in the converter 10 on the distribution side or provided outside the converter 10 on the distribution side and connected to the distribution line. The operation unit 120 calculates wiring resistance, a power sum, a loss sum, and the like, and the control unit 130 determines the presence or absence of an abnormality (accident, or the like) based on the operation result from the operation unit 120, and performs alarm display and gate block control. Details of the processing of the operation unit 120 and the control unit 130 will be described later. The operation unit 120 and the control unit 130 may be integrally formed as a “control unit”.

The storage unit 140 stores the operation result from the operation unit 120 such as the wiring resistance. The storage unit 140 may store information such as a current value, a voltage value, a power value, a loss of each path, and the like of each base.

The communication unit 160 receives a current value and a voltage value on the input side of the converter 20 at each base on the power reception side from the control device 200 at each base on the power reception side. Further, the communication unit 160 can transmit a current value, a voltage value, or an operation result (wiring resistance, wiring loss, or the like) to the learning device 300.

The display unit 150 displays the determination result from the control unit 130. In addition, the display unit 160 may be a lamp such as an LED or the like on the exterior of the converter 10, and in this case, for example, when abnormality is detected, the lamp is turned on. Furthermore, the display unit 160 may transmit a signal to a monitoring system that monitors each base.

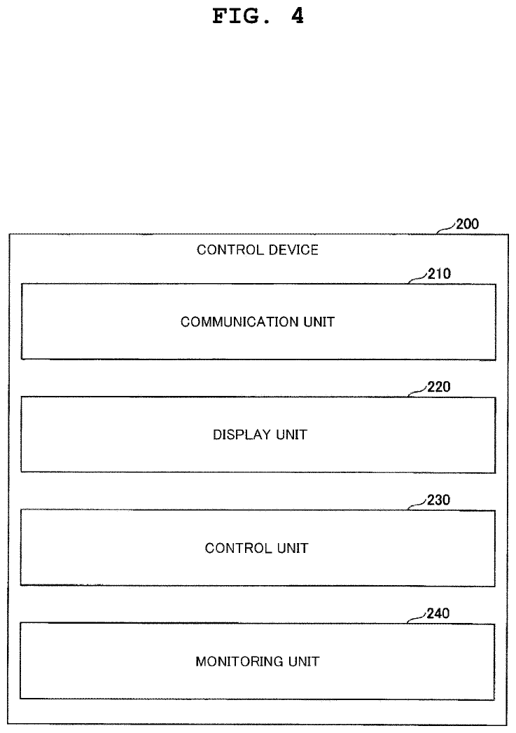

FIG. 4 is a diagram illustrating a configuration example of a control device 200 at each base on the power reception side. As illustrated in FIG. 4, the control device 200 includes a communication unit 210, a monitoring unit 220, a control unit 230, and a display unit 240.

The monitoring unit 240 reads values of a current meter and a voltmeter built in the converter 20 or provided outside the converter 20 and connected to a distribution line. The communication unit 210 transmits the current value and the voltage value acquired by the monitoring unit 240 to the control device 100 at the base A. In addition, the communication unit 210 receives the abnormality detection result obtained by the control device 100.

The control unit 230 controls, for example, the converter 20 to operate the gate block function when it receives a result indicating an abnormality from the control device 100.

The display unit 220 displays the abnormality detection result received from the communication unit 210. In addition, the display unit 220 may be a lamp such as an LED or the like on the exterior of the converter 20, and in this case, for example, when abnormality is detected, the lamp is turned on. Furthermore, the display unit 220 may transmit a signal to a monitoring system that monitors each base.

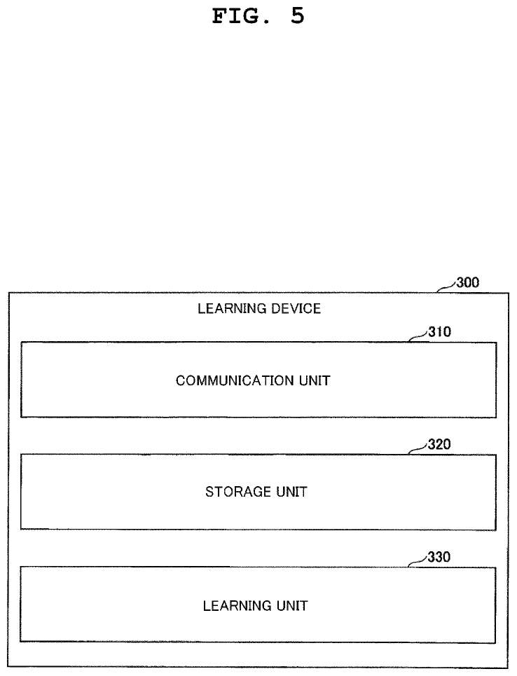

FIG. 5 is a diagram illustrating a configuration example of the learning device 300. As illustrated in FIG. 5, the learning device 300 includes a communication unit 310, a storage unit 320, and a learning unit 330. The communication unit 310 receives learning data from the control device 100 and the like (for example: values obtained from measuring instruments, wiring resistance, wiring loss, or the like, and corresponding event data (for example: short circuit on the path to base C)), and stores the learning data in the storage unit 320. The learning unit 330 performs learning using the learning data. For example, as will be described later, the model of the neural network is learned. The communication unit 3100 transmits the learned model to the control device 100 or the like.

### <Hardware Configuration Example>

The control devices 100 and 200 and the learning device 300 can all be realized by, for example, causing a computer to execute a program. This computer may be a physical computer or a virtual machine.

That is, the devices (the control devices 100 and 200 and the learning device 300) can be realized by executing a program corresponding to the processing executed by the device with use of hardware resources such as a CPU and a memory built in a computer. The program can be recorded on a computer-readable recording medium (portable memory, and the like), stored, and distributed. It is also possible to provide the program via a network such as the Internet or an electronic mail.

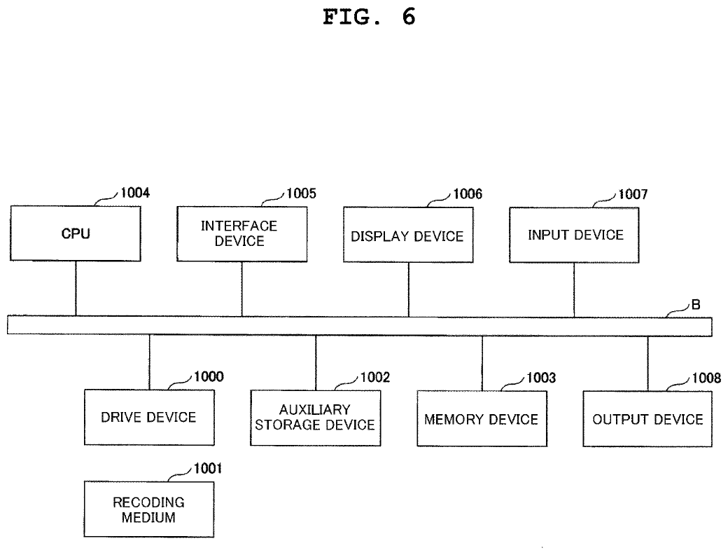

FIG. 6 is a diagram illustrating an exemplary hardware configuration of the computer. The computer illustrated in FIG. 6 has a drive device 1000, an auxiliary storage device 1002, a memory device 1003, a CPU 1004, an interface device 1005, a display device 1006, an input device 1007, an output device 1008, and the like, which are connected to each other by a bus B.

A program for realizing processing in the computer is provided by, for example, a recording medium 1001 such as a CD-ROM or a memory card. When the recording medium 1001 having the program stored therein is set in the drive device 1000, the program is installed in the auxiliary storage device 1002 from the recording medium 1001 via the drive device 1000. However, the program does not necessarily have to be installed from the recording medium 1001, and may be downloaded from another computer via a network. The auxiliary storage device 1002 stores the installed program and also stores necessary files, data, and the like.

The memory device 1003 reads and stores the program from the auxiliary storage device 1002 when there is an instruction to start the program. The CPU 1004 implements the function related to the device in accordance with the program stored in the memory device 1003. The interface device 1005 is used as an interface for connecting to a network, and functions as a transmission unit and a reception unit. The display device 1006 displays a graphical user interface (GUI) or the like according to a program. The input device 1007 is configured with a keyboard, a mouse, a button, a touch panel, or the like, and is used to input various operation instructions. The output device 1008 outputs a calculation result.

### (Operation Flow)

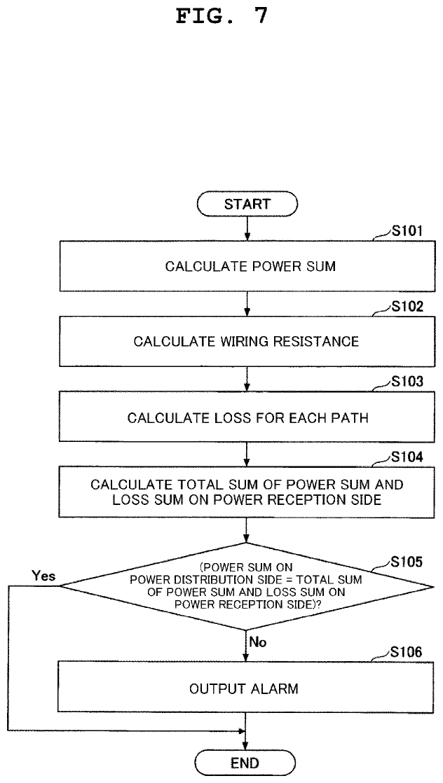

Next, referring to the flow chart of FIG. 7, the operation of the control device 100 installed at the base of the power distribution side for detecting abnormality will be described in detail. The flow chart of FIG. 7 is executed at regular intervals (for example, a 1 ms second interval, a 1 second interval, a few seconds interval, a 1 minute interval, or the like), and every time the flow chart of FIG. 7 is executed, the current value, the voltage value, and the calculation result (wiring resistance, loss, or the like) obtained from the measuring instrument are stored in the storage unit 140 together with the time stamp.

### <S101>

The monitoring unit 110 reads values of the current meter and the voltmeter on the power distribution side to acquire the voltage value and the current value on the output side of the converter 10 on the power distribution side. In addition, the communication unit 160 receives the voltage value and the current value on the input side of the converter 20 on the power reception side acquired at each base on the power reception side.

The operation unit 120 calculates the power value on the distribution side (distribution power value) from the voltage value (distribution voltage value) and the current value (distribution current value) on the distribution side and the power value of each base on the power reception side (received power value) from the voltage value (received voltage value) and the current value (received current value) of each base on the power reception side.

Assuming that the voltage value, current value, and power value on the distribution side are defined as V₁, I₁, and P₁, respectively, P₁ is calculated by P₁=V₁×I₁ respectively,

Assuming that the voltage value, current value, and power value of the base n on the power reception side are V₂ₙ, I₂ₙ, and P₂ₙ, respectively, P₂ₙ is calculated by P₂ₙ=V₂ₙ×I₂ₙ.

In the example of FIG. 1, assuming that the received current values of the bases B, C, and D are defined as I_{2b}, I_{2c}, and I_{2d}, and the received voltage values of the bases B, C, and D are V_{2b}, V_{2c}, and V_{2d}, respectively, the received power values P_{2b}, P_{2c}, and P_{2d} of each of the base B, the base C, and the base D are calculated as follows.

P_{2b}=V_{2b}×I_{2b}

P_{2c}=V_{2c}×I_{2c}

P_{2d}=V_{2d}×I_{2d}

Further, the operation unit 120 calculates the sum of power on the power distribution side and the power reception side, respectively. In this embodiment, since the power value on the distribution side (power value before branching into three) is one, the sum of power is P₁ described above. In a case where the power sum is calculated using the voltage value and the current value after branching into three on the power distribution side, the power sum on the power distribution side is calculated as P₁ by adding the respective voltage value X the current value.

The power sum on the power reception side is calculated by ΣP₂ₙ. Σ represents the sum of the number of bases on the power reception side. In the example illustrated in FIG. 1, the calculation is performed as follows.

ΣP₂ₙ=P_{2b}+P_{2c}+P_{2d}

### <S102>

In S102, the operation unit 120 calculates the wiring resistance for each path (path n) of the distribution line from the distribution side base to each power reception side base. Assuming that the wiring resistance between the base on the distribution side and a base n on the power reception side is Rₙ, Rₙ is calculated as follows:

Rₙ=(V₁−V₂ₙ)/I₂ₙ

That is, the result of dividing the voltage drop of the path n from the power distribution side base to the power reception side base n by the value of the current flowing through the path n becomes Rₙ. In the example illustrated in FIG. 1, the calculation is performed as follows.

Rb=(V₁−V_{2b})/I_{2b}

Rc=(V₁−V_{2c})/I_{2c}

Rd=(V₁−V_{2d})/I_{2d}

The value of the wiring resistance here is stored in the storage unit 140 and notified to the control unit 130. The control unit 130 compares the calculated wiring resistance with the past wiring resistance stored in the storage unit 140, and in a case where the difference is larger than the threshold value, the control unit 130 instructs the display unit 150 to output an alarm, and the display unit 150 outputs an alarm.

As an example, for example, when it is detected that the value obtained by subtracting the current Rc from the Rc at the time of the previous calculation is larger than the threshold value, the control unit 130 instructs the display unit 150 to output an alarm indicating that there is an abnormality in the distribution line between the base A and the base C, and the display unit 150 outputs the alarm. Further, the communication unit 160 may transmit a signal indicating that there is an abnormality in the distribution line between the base a and the base C to the control device 200 of each base, and display a similar alarm at each base.

### <S103>

In S103, the operation unit 120 calculates the loss (wiring loss) for each path. Assuming that the loss of the path n from the distribution side base to the power reception side base n is Lₙ, Lₙ is calculated as follows:

Lₙ=I²₂ₙ×Rₙ.

In the example illustrated in FIG. 1, the calculation is performed as follows.

L_{b}=I²_{2b}×R_{b}

L_{c}=I²_{2c}×R_{c}

L_{d}=I²_{2d}×R_{d}

### <S104>

in S104, the operation unit 120 first obtains the total sum of losses. The total sum of losses is calculated by ΣLₙ. Σ is the sum of the number of power reception side bases. In the example illustrated in FIG. 1, the calculation is performed as follows.

ΣLₙ=L_{b}+L_{c}+L_{d}

Subsequently, the operation unit 120 sums the power sum and the loss sum on the power reception side. In the example illustrated in FIG. 1, the calculation is performed as follows.

ΣP₂ₙ+ΣLₙ=P_{2b}+P_{2c}+P_{2d}+L_{b}+L_{c}+L_{d}

### <S105>

The control unit 130 compares the power sum on the output side with the “power sum+loss sum” on the input side to determine whether they match. That is, it is determined whether “P₁=P₂ₙ+Lₙ” is established. Here, the “match” is not limited to the perfect match, but may be regarded as “match” if the difference is within a predetermined threshold. That is, assuming that the threshold value is TH, S105 may be to determine whether or not “|P₁−(ΣP₂ₙ+ΣLₙ)|<TH” is satisfied.

If the determination result in S105 is Yes, the processing is terminated. In a case where the determination in S105 is Yes, information indicating normal may be displayed from the display unit 150. When the determination result is No in S105, the processing proceeds to S106.

### <S106>

The power sum on the output side and the “power sum+loss sum” on the input side should be matched if there is no abnormality in the distribution network. In S105, when the power sum of the output side and the “power sum+loss sum” on the input side do not match, it means that there is abnormality in the distribution network. The abnormality is, for example, an accident such as a ground fault or a short circuit.

In S106, the control unit 130 determines that there is an abnormality in the distribution network, instructs the display unit 150 to output an alarm indicating that there is an abnormality in the distribution network, and the display unit 150 outputs the alarm. Further, the communication unit 160 may transmit a signal indicating that there is an abnormality in the distribution network to the control device 200 at each base, and display a similar alarm at each base.

In addition, the control device 100 may stop the power distribution by operating the gate block of the converter 10 on the power distribution side.

### (About Learning)

As described above, in addition to detecting an abnormality by comparing the power sum on the output side with the “power sum the loss sum” on the input side, it is also possible to detect an abnormality by learning by the learning device 300 as described below.

In a case where an abnormality such as a around fault or a short circuit occurs, wiring resistance or wiring loss in a path where the abnormality occurs changes. Then, the control device 200 transmits the calculated wiring resistance or wiring loss to the learning device 300, and the learning device 300 learns the relationship between the received value and the generated event from the value and the generated event.

The learning technique is not limited to a specific method, but may be a model of a neural network, for example. As an example, an example of learning about a short circuit and a ground fault in the configuration illustrated in FIG. 1 will be described. First, as an example of data when an abnormality occurs in a certain path in a distribution network (the wiring resistance and wiring loss of each of the paths b, c and d, and a number of pieces of information on which path the abnormality has occurred) are acquired as learning data. The learning data may be obtained by computer simulation or the like.

The learning device 300 inputs the wiring resistance and wiring loss of each of the path b, the path c, and the path d which are learning data to a model, and the parameter of the model is learned so that the output corresponding to the data is the correct event (for example: a short circuit in the path c). Then, the learned model is stored in the storage unit 140 of the control device 200. The control unit 130 of the control device 200 inputs the calculated wiring resistance and wiring loss to the model, and can determine the presence or absence of abnormality by an output from the model.

In the above example, the wiring resistance and the wiring loss are used for learning, but this is an example. The learning may be performed using other values (for example: distribution voltage, distribution current and received voltage, and received current at each base).

### (Example of Topology)

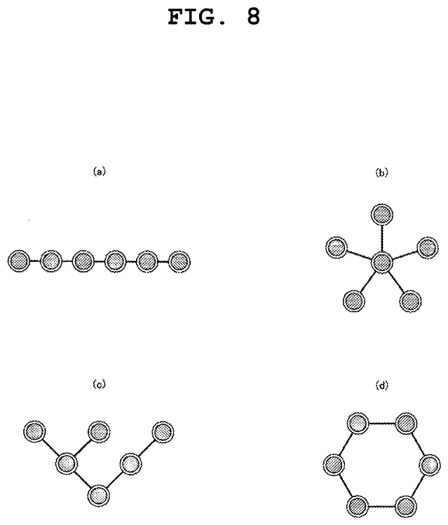

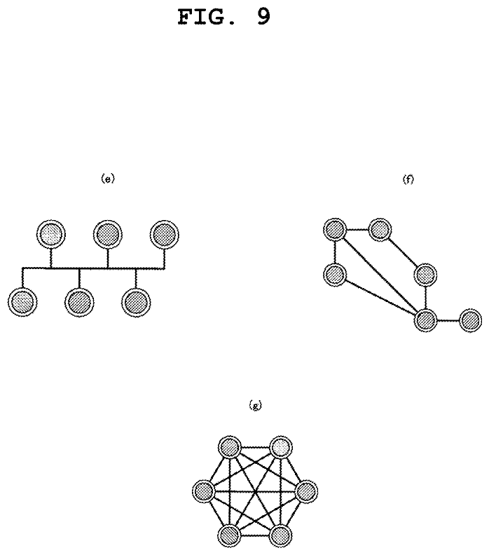

In this embodiment, an example of one base to a plurality of bases has been described, the technique according to the present invention can be applied not only to a one-site to a plurality of sites but also to a DC power distribution system having a multi-site to a plurality of-site topology. Further, the technique according to the present invention can be applied to (a) a line-type topology in which a plurality of bases are connected in a straight line, (b) a star-type topology in which each base is connected around a hub base, (c) a tree-type topology in which a plurality of bases are connected in a tree shape, (d) a ring-type topology in which a plurality of bases are connected in a ring shape, (e) a bus-type topology in which a plurality of bases are connected in a bus shape, (f) a mesh-type topology in which a plurality of bases are connected to a mesh, and (g) a full mesh type topology in which a plurality of bases are connected by a full mesh as shown in FIGS. 8 and 9.

### Effects of Embodiment

As described above, according to the present embodiment, it is possible to detect an abnormality that has occurred in the DC power distribution system.

In addition, short circuits and ground faults can be detected without using a special relay to protect the DC distribution network. It is also possible to use a protective element such as a fuse and an MCCB in combination. Further, the resistance value and wiring loss of the distribution line are stored as data, and a model is constructed by learning, and secondary utilization can be realized. In addition, it can be used for multiple-to-multiple power distribution and various topologies, and since each base is connected by a network, it is possible to ascertain the power information of all bases in detail. In addition, state monitoring can be performed without stopping the power supply.

### Conclusion of Embodiment

in the present specification, at least a DC power distribution system, a control device, an abnormality detection method, and a program described in each item are described.

### (Item 1)

A DC power distribution system for performing DC power distribution from a power distribution side base to one or more power reception side bases via a power distribution network, the system including:
measuring instruments provided at the power distribution side base and at the one or more power reception side bases, and
a control device, in which
the control device includes
an operation unit that acquires a voltage value and a current value measured by the measuring instrument and calculates an output side power sum that is a sum of power output from the power distribution side base, a power reception side power sum that is a sum of power input to the one or more power reception side bases, and a loss sum between the power distribution side base and the one or more power reception side bases, and
a control unit that detects an abnormality in the distribution network by comparing the output side power sum with a total sum of the power reception side power sum and the loss sum.

### (Item 2)

The DC power distribution system according to Item 1, in which the control unit determines that, when the output side power sum does not match the total sum of the power reception side power sum and the loss sum, an abnormality has occurred in the distribution network.

### (Item 3)

The DC power distribution system according to Item 1 or 2, further including:
a learning device that learns a model that models a relationship between wiring resistance and wiring loss for each path and events occurring in the distribution network using the wiring resistance and wiring loss for each path calculated by the operation unit and the event occurring in the distribution network.

### (Item 4)

A control device that performs abnormality detection in a DC power distribution system that performs power distribution from a power distribution side base to one or more power reception side bases via a power distribution network, the control device including:
an operation unit that acquires a voltage value and a current value measured by measuring instruments provided at each of the power distribution side base and the one or more power reception side bases, and calculates an output side power sum that is a sum of power output from the power distribution side base, a power reception side power sum that is a sum of power input to the one or more power reception side bases, and a loss sum between the power distribution side base and the one or more power reception side bases; and
a control unit that detects an abnormality in the distribution network by comparing the output side power sum with a total sum of the power reception side power sum and the loss sum.

### (Item 5)

An abnormality detection method executed by a control device in a DC power distribution system that distributes DC power from a power distribution side base to one or more power reception side bases via a power distribution network, the method including:
a step of acquiring a voltage value and a current value measured by measuring instruments provided at each of the power distribution side base and the one or more power reception side bases, and calculating an output side power sum that is a sum of power output from the power distribution side base, a power reception side power sum that is a sum of power input to the one or more power reception side bases, and a loss sum between the power distribution side base and the one or more power reception side bases; and
a step of detecting an abnormality in the distribution network by comparing the output side power sum with a total sum of the power reception side power sum and the loss sum.

### (Item 6)

A program for causing a computer to function as each unit of the control device according to Item 4.

Although the embodiment has been described above, the present invention is not limited to such a specific embodiment, and various modifications and changes can be made within the scope of the gist of the present invention described in the claims.

### REFERENCE SIGNS LIST

10, 20 Converter
100, 200 Control device
110, 240 Monitoring unit
120 Operation unit
130, 230 Control unit
140 Storage unit
150, 220 Display unit
160, 210 Communication unit
300 Learning device
310 Communicating unit
320 Storage unit
330 Learning unit
1000 Drive device
1001 Recording medium
1002 Auxiliary storage device
1003 Memory device
1004 CPU
1005 Interface device
1006 Display device
1007 Input device

1. A DC power distribution system for performing DC power distribution from a power distribution side base to one or more power reception side bases via a power distribution network, the system comprising:
measuring instruments provided at the power distribution side base and at the one or more power reception side bases, and
a control device, wherein
the control device includes:
a memory; and
a processor coupled to the memory and configured to
acquire a voltage value and a current value measured by the measuring instrument;
calculate an output side power sum that is a sum of power output from the power distribution side base, a power reception side power sum that is a sum of power input to the one or more power reception side bases, and a loss sum between the power distribution side base and the one or more power reception side bases; and
detect an abnormality in the distribution network by comparing the output side power sum with a total sum of the power reception side power sum and the loss sum.

2. The DC power distribution system according to claim 1, wherein the processor is configured to determine that an abnormality has occurred in the distribution network when the output side power sum does not match the total sum of the power reception side power sum and the loss sum.

3. The DC power distribution system according to claim 1, further comprising:
a learning device including a memory and a processor configured to learn a model that models a relationship between wiring resistance and wiring loss for each path and events occurring in the distribution network using the wiring resistance and wiring loss for each path calculated by the processor of the control device and the event occurring in the distribution network.

4. A control device that performs abnormality detection in a DC power distribution system that performs power distribution from a power distribution side base to one or more power reception side bases via a power distribution network, the control device comprising:
a memory; and
a processor coupled to the memory and configured to
acquire a voltage value and a current value measured by measuring instruments provided at each of the power distribution side base and the one or more power reception side bases;
calculate an output side power sum that is a sum of power output from the power distribution side base, a power reception side power sum that is a sum of power input to the one or more power reception side bases, and a loss sum between the power distribution side base and the one or more power reception side bases; and
detect an abnormality in the distribution network by comparing the output side power sum with a total sum of the power reception side power sum and the loss sum.

5. An abnormality detection method executed by a control device in a DC power distribution system that distributes DC power from a power distribution side base to one or more power reception side bases via a power distribution network, the method comprising:
acquiring a voltage value and a current value measured by measuring instruments provided at each of the power distribution side base and the one or more power reception side bases;
calculating an output side power sum that is a sum of power output from the power distribution side base, a power reception side power sum that is a sum of power input to the one or more power reception side bases, and a loss sum between the power distribution side base and the one or more power reception side bases; and
detecting an abnormality in the distribution network by comparing the output side power sum with a total sum of the power reception side power sum and the loss sum.

6. A non-transitory computer readable medium having a program embodied therein for causing a computer to perform the abnormality detection method of claim 5.
